(19) United States
(12) Patent Application Publication
(10) Pub. No.: US 2026/0082975 A1
(43) Pub. Date: Mar. 19, 2026

(54) ELECTRONIC COMPONENT WITH STACKED BARRIER STRUCTURE, INTERMEDIATE STRUCTURE COMPRISING NICKEL, AND COPPER AND/OR ALUMINIUM STRUCTURE

(71) Applicant: Infineon Technologies AG, Neubiberg (DE)

(72) Inventors: Rainer Ludwig PELZER, Wernberg (AT); Andreas KLEINBICHLER, Klagenfurt am Wörthersee (AT); Tobias POLSTER, Finkenstein (AT)

(73) Assignee: Infineon Technologies AG, Neubiberg (DE)

(21) Appl. No.: 19/320,294

(22) Filed: Sep. 5, 2025

(30) Foreign Application Priority Data
Sep. 16, 2024 (DE) 10 2024 126 594.9

(51) Int. Cl. H01L 23/00

(52) U.S. Cl. CPC H10W 72/90; H10W 72/019; H10W 72/30; H10W 72/50; H10W 72/60; H10W 72/851; H10W 72/01938; H10W 72/01953; H10W 72/871; H10W 72/884; H10W 72/886; H10W 72/923; H10W 72/952; H10W 90/736; H10W 90/756; H10W 90/766

(57) ABSTRACT

An electronic component is disclosed. In one example, the electronic component comprises a semiconductor body, an active region in the semiconductor body, at least one metallization structure arranged on or above the active region and comprising a stack. The stack includes a barrier structure, an intermediate structure on the barrier structure and comprising nickel, and a copper and/or aluminium structure on the intermediate structure and comprising copper and/or aluminium. A dielectric structure is connected to a sidewall of the stack.

### CROSS-REFERENCE TO RELATED APPLICATION

This Utility patent application claims priority to German Patent Application No. 10 2024 126 594.9 filed Sep. 16, 2024, which is incorporated herein by reference.

### BACKGROUND

### Technical Field

Various embodiments relate generally to electronic components, a package, and methods of manufacturing an electronic component.

### Description of the Related Art

A conventional package may comprise for example an electronic component mounted on a chip carrier such as a leadframe, may be electrically connected by a bond wire extending from the chip to the chip carrier or to a lead, and may be molded using a mold compound as an encapsulant.

### SUMMARY

There may be a need for an electronic component with high reliability and reasonable manufacturing effort.

According to an exemplary embodiment of a first aspect, an electronic component is provided which comprises a semiconductor body, an active region in the semiconductor body, at least one metallization structure arranged on or above the active region and comprising a stack having a barrier structure, an intermediate structure on the barrier structure and comprising nickel, and a copper and/or aluminium structure on the intermediate structure and comprising copper and/or aluminium, and a dielectric structure connected to a sidewall of the stack.

According to another exemplary embodiment of the first aspect, a method of manufacturing an electronic component is provided, wherein the method comprises forming an active region in a semiconductor body, forming at least one metallization structure on or above the active region and with a stack having a barrier structure, an intermediate structure on the barrier structure and comprising nickel, and a copper and/or aluminium structure on the intermediate structure and comprising copper and/or aluminium, and connecting a dielectric structure to a sidewall of the stack.

According to an exemplary embodiment of a second aspect, an electronic component is provided which comprises a semiconductor body, an active region in the semiconductor body, and at least one metallization structure on an opposing side of the semiconductor body with respect to the active region and comprising a stack having a barrier structure, an intermediate structure on the barrier structure and comprising nickel, and a copper and/or aluminium structure on the intermediate structure and comprising copper and/or aluminium, wherein a surface of the semiconductor body on which the at least one metallization structure is arranged has a roughness Ra of at least 1 μm.

According to another exemplary embodiment of the second aspect, a method of manufacturing an electronic component is provided, wherein the method comprises forming an active region in a semiconductor body, forming at least one metallization structure on an opposing side of the semiconductor body with respect to the active region and with a stack having a barrier structure, an intermediate structure on the barrier structure and comprising nickel, and a copper and/or aluminium structure on the intermediate structure and comprising copper and/or aluminium, and arranging the at least one metallization structure on a surface of the semiconductor body which has a roughness Ra of at least 1 μm.

According to another exemplary embodiment (which may relate in particular to the first aspect and/or to the second aspect), a package is provided which comprises a carrier, and an electronic component having the above-mentioned features and being mounted on and/or in the carrier, wherein at least one of the at least one metallization structure of the electronic component is electrically coupled with the carrier.

According to an exemplary embodiment of the first aspect, an electronic component (such as a semiconductor die) has a semiconductor body or substrate with an active region integrated therein. A metallization structure, preferably a stack of at least three structures, may be formed in particular as front side metallization on or above the active region. Said stack may have a barrier structure which may function as diffusion barrier and/or for suppressing migration of material, an intermediate structure which may comprise nickel and which may function as adhesion promoter and/or for preventing corrosion, and a copper and/or aluminium structure which may enable solderability or electric connectivity. Optionally, a dielectric structure (for instance comprising polyimide) may be connected laterally to the stack for spatially delimiting the metallization structure with respect to surrounding structures. This may increase the electric reliability of the electronic component and of the corresponding package. Advantageously, the mentioned front side metallization may enable contamination friendly etching and may provide manufacturing stability while reliably suppressing contamination.

According to an exemplary embodiment of the second aspect, an electronic component (such as a semiconductor die) has a semiconductor body or substrate with an active region integrated therein. A metallization structure, preferably a stack of at least three structures, may be formed in particular as back side metallization on a side opposing or facing away from the active region. Said stack may have a barrier structure which may function as diffusion barrier and/or for suppressing migration of material, an intermediate structure which may comprise nickel and which may function as adhesion promoter and/or for preventing corrosion, and a copper and/or aluminium structure which may enable solderability. Optionally, the metallization structure may be formed even on a rough semiconductor body having a roughness Ra of 1 μm or more. Thus, no specific requirements concerning the smoothness of the semiconductor need to be fulfilled for applying said back side metallization structure. This may simplify a manufacturing process.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a cross-sectional view of a package with an electronic component surface mounted on a carrier according to an exemplary embodiment.

FIG. 2 illustrates an image of a stack of a metallization structure of an electronic component according to an exemplary embodiment.

FIG. 3 illustrates a cross-sectional view of an electronic component according to an exemplary embodiment.

FIG. 4 illustrates a cross-sectional view of an electronic component according to another exemplary embodiment.

FIG. 5 illustrates a cross-sectional view of an electronic component according to another exemplary embodiment.

FIG. 6 illustrates a cross-sectional view of an electronic component according to another exemplary embodiment.

FIG. 7 illustrates a cross-sectional view of an electronic component according to another exemplary embodiment.

FIG. 8 illustrates a cross-sectional view of an electronic component according to another exemplary embodiment.

FIGS. 9 and 10 illustrate diagrams showing a characteristic of an electronic component according to exemplary embodiments.

FIG. 11 illustrates a cross-sectional view of an electronic component according to another exemplary embodiment.

FIG. 12 illustrates an image of a stack of a metallization structure of an electronic component according to an exemplary embodiment.

FIG. 13 illustrates a cross-sectional view of an electronic component according to another exemplary embodiment.

FIG. 14 illustrates a cross-sectional view of an electronic component according to another exemplary embodiment.

FIG. 15 illustrates a cross-sectional view of an electronic component according to another exemplary embodiment.

FIG. 16 illustrates a cross-sectional view of an electronic component according to another exemplary embodiment.

FIG. 17 illustrates a cross-sectional view of a package with an electronic component according to an exemplary embodiment.

FIG. 18 illustrates a cross-sectional view of a package with electronic components embedded in a carrier according to an exemplary embodiment.

### DETAILED DESCRIPTION

There may be a need for an electronic component with high reliability and reasonable manufacturing effort.

According to an exemplary embodiment of a first aspect, an electronic component is provided which comprises a semiconductor body, an active region in the semiconductor body, at least one metallization structure arranged on or above the active region and comprising a stack having a barrier structure, an intermediate structure on the barrier structure and comprising nickel, and a copper and/or aluminium structure on the intermediate structure and comprising copper and/or aluminium, and a dielectric structure connected to a sidewall of the stack.

According to another exemplary embodiment of the first aspect, a method of manufacturing an electronic component is provided, wherein the method comprises forming an active region in a semiconductor body, forming at least one metallization structure on or above the active region and with a stack having a barrier structure, an intermediate structure on the barrier structure and comprising nickel, and a copper and/or aluminium structure on the intermediate structure and comprising copper and/or aluminium, and connecting a dielectric structure to a sidewall of the stack.

According to an exemplary embodiment of a second aspect, an electronic component is provided which comprises a semiconductor body, an active region in the semiconductor body, and at least one metallization structure on an opposing side of the semiconductor body with respect to the active region and comprising a stack having a barrier structure, an intermediate structure on the barrier structure and comprising nickel, and a copper and/or aluminium structure on the intermediate structure and comprising copper and/or aluminium, wherein a surface of the semiconductor body on which the at least one metallization structure is arranged has a roughness Ra of at least 1 μm.

According to another exemplary embodiment of the second aspect, a method of manufacturing an electronic component is provided, wherein the method comprises forming an active region in a semiconductor body, forming at least one metallization structure on an opposing side of the semiconductor body with respect to the active region and with a stack having a barrier structure, an intermediate structure on the barrier structure and comprising nickel, and a copper and/or aluminium structure on the intermediate structure and comprising copper and/or aluminium, and arranging the at least one metallization structure on a surface of the semiconductor body which has a roughness Ra of at least 1 μm.

According to another exemplary embodiment (which may relate in particular to the first aspect and/or to the second aspect), a package is provided which comprises a carrier, and an electronic component having the above-mentioned features and being mounted on and/or in the carrier, wherein at least one of the at least one metallization structure of the electronic component is electrically coupled with the carrier.

According to an exemplary embodiment of the first aspect, an electronic component (such as a semiconductor die) has a semiconductor body or substrate with an active region integrated therein. A metallization structure, preferably a stack of at least three structures, may be formed in particular as front side metallization on or above the active region. Said stack may have a barrier structure which may function as diffusion barrier and/or for suppressing migration of material, an intermediate structure which may comprise nickel and which may function as adhesion promoter and/or for preventing corrosion, and a copper and/or aluminium structure which may enable solderability or electric connectivity. Optionally, a dielectric structure (for instance comprising polyimide) may be connected laterally to the stack for spatially delimiting the metallization structure with respect to surrounding structures. This may increase the electric reliability of the electronic component and of the corresponding package. Advantageously, the mentioned front side metallization may enable contamination friendly etching and may provide manufacturing stability while reliably suppressing contamination.

According to an exemplary embodiment of the second aspect, an electronic component (such as a semiconductor die) has a semiconductor body or substrate with an active region integrated therein. A metallization structure, preferably a stack of at least three structures, may be formed in particular as back side metallization on a side opposing or facing away from the active region. Said stack may have a barrier structure which may function as diffusion barrier and/or for suppressing migration of material, an intermediate structure which may comprise nickel and which may function as adhesion promoter and/or for preventing corrosion, and a copper and/or aluminium structure which may enable solderability. Optionally, the metallization structure may be formed even on a rough semiconductor body having a roughness Ra of 1 μm or more. Thus, no specific requirements concerning the smoothness of the semiconductor need to be fulfilled for applying said back side metallization structure. This may simplify a manufacturing process.

### DESCRIPTION OF FURTHER EXEMPLARY EMBODIMENTS

In the following, further exemplary embodiments of the electronic components, the package and the methods will be explained.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). However, in other embodiments, the electronic component may also be of different type, such as a mechatronic member, in particular a mechanical switch, etc. In particular, the electronic component may be a semiconductor chip having at least one integrated circuit element (such as a diode or a transistor in a surface portion thereof. The electronic component may be a bare die or may be already packaged or encapsulated. Semiconductor chips implemented according to exemplary embodiments may be formed in silicon technology, gallium nitride technology, silicon carbide technology, etc.

In the context of the present application, the term “semiconductor body” may in particular denote a body comprising a semiconductor material. The semiconductor body may be initially part of a semiconductor wafer and may be separated from the wafer compound during a manufacturing process. For example, the semiconductor body comprises silicon or silicon carbide. The semiconductor body may be predominantly made of a semiconductor material. For instance, the semiconductor body may be a plate-shaped structure or a cuboid-shaped structure.

In the context of the present application, the term “active region” may in particular denote a portion of a semiconductor body in which at least one integrated circuit element is formed or integrated. For instance, such an integrated circuit element may be monolithically integrated in the semiconductor body. For instance, such an integrated circuit element may be a diode, a transistor, an ohmic resistance, a capacitance or an inductance.

In the context of the present application, the term “metallization structure” may in particular denote a stacked structure comprising different metals and being applied on a front side and/or a back side of a semiconductor body of a semiconductor die-type electronic component. By a metallization structure, an electric connection of the electronic component with respect to an electronic environment, for instance in a package and/or between a package and an electronic environment thereof, may be established.

In the context of the present application, the term “stack” may in particular denote a plurality of structures (in particular three or at least three structures) applied on top of each other. For instance, said stack may be a layer stack of planar and/or curved layers or may be a stack of non-layer structures.

In the context of the present application, the term “barrier structure” may in particular denote a structure, preferably a layer, made of a material functioning as a barrier between different constituents of an electronic component. The barrier structure, which may comprise titanium, may suppress phenomena such as diffusion or migration of material.

In the context of the present application, the term “intermediate structure” may in particular denote a structure arranged in between a barrier structure and another metal structure (in particular based on copper and/or aluminium) which may promote adhesion between said two structures and/or may prevent corrosion phenomena.

In the context of the present application, the term “copper and/or aluminium structure” may in particular denote an exterior structure of a metallization stack on which an electrically conductive connection of an electronic component may be established with another member or element (in particular by soldering), and/or on which a further metallic structure may be formed (for instance by electroplating). For example, the copper and/or aluminium structure may be solderable and/or may be a seed layer for galvanic plating. In one embodiment, the copper and/or aluminium structure may consist of copper only. In another embodiment, the copper and/or aluminium structure may consist of aluminium only. In yet another embodiment, the copper and/or aluminium structure may comprise copper and aluminium, such as AlCu. The copper and/or aluminum structure may be a metallic structure or an alloy structure.

In the context of the present application, the term “dielectric structure” may in particular denote an electrically insulating structure which may ensure or support physical separation and electric insulation of a metallization stack with respect to another member or element. For instance, the dielectric structure may be a bulky block. A bulky block may be distinguished from a tiny thin-film.

In the context of the present application, the term “sidewall of the stack” may in particular denote a lateral surface of a stacked metallization structure. Such a sidewall may be in particular vertical and/or slanted with respect to a horizontal plane.

In the context of the present application, the term “roughness Ra” may in particular denote an average roughness being a parameter which specifies a surface texture. The roughness Ra may provide a measure of the height of the texture across a surface. In particular, roughness Ra may be the average of how far each point on the surface deviates in height from the mean height. In particular, roughness Ra may be measured by a stylus based measurement instrument. In a stylus based measurement instrument, a tip is dragged across a surface while its deflection is recorded. The roughness Ra may denote an arithmetic average value of a roughness profile which may be determined from deviations about a center line within an evaluation length.

In the context of the present application, the term “package” may particularly denote an electronic device which may comprise one or more electronic components mounted on a (in particular at least partially electrically conductive) carrier. Said constituents of the package may be optionally encapsulated at least partially by an encapsulant. Further optionally, one or more electrically conductive interconnect bodies (such as metallic pillars, bumps, bond wires and/or clips) may be implemented in a package, for instance for electrically coupling and/or mechanically supporting the electronic component.

In the context of the present application, the term “carrier” may particularly denote a support structure (which may be at least partially electrically conductive) which serves as a mechanical support for the electronic component(s) to be mounted thereon, and which may also contribute to the electric interconnection between the electronic component(s) and the periphery of the package. In other words, the carrier may fulfil a mechanical support function and an electric connection function. A carrier may comprise or consist of a single part, multiple parts joined via encapsulation or other package components, or a subassembly of carriers. When the carrier forms part of a leadframe, it may be or may comprise a die pad.

However, the carrier may also be a laminate which comprises a plurality of laminated layers. In the context of the present application, the term “laminate” may particularly denote a flat body (such as a sheet or plate) formed by multiple interconnected laminate layers, i.e. layers which can be or which are interconnected by lamination. In particular, a laminate may comprise a material that is suitable for sticking several laminate layers, for instance made of the same material, together. Hence, a laminate may be a plate-shaped or sheet-shaped body made of one or multiple laminable or laminated layers. Said laminate layers may be connected or configured to be connectable with other layers by lamination. Lamination may denote a connection of laminable layers using elevated temperature, optionally accompanied by an additional mechanical pressure applied to stacked laminate layers. In particular, such a laminate may be a pressed multilayer stack of one or more dielectric organic layers and/or one or more metallic foils. One or more dielectric laminate layers may be for example prepreg layers. Prepreg is a material which comprises a resin, optionally with glass fibres therein. The laminate may also comprise one or more metal layers, which may be copper foils. More generally, the laminate may comprise at least one dielectric layer which is capable of curing, polymerizing and/or cross-linking during a lamination process, thereby contributing to an adhesion force between multiple layers of a multilayer laminate. For instance, a laminate may be a printed circuit board (PCB).

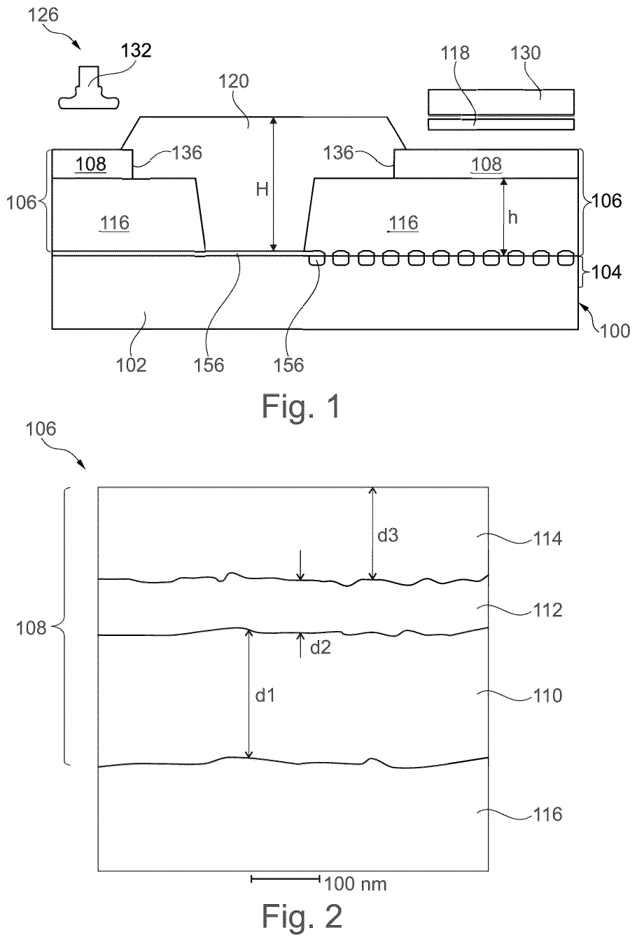

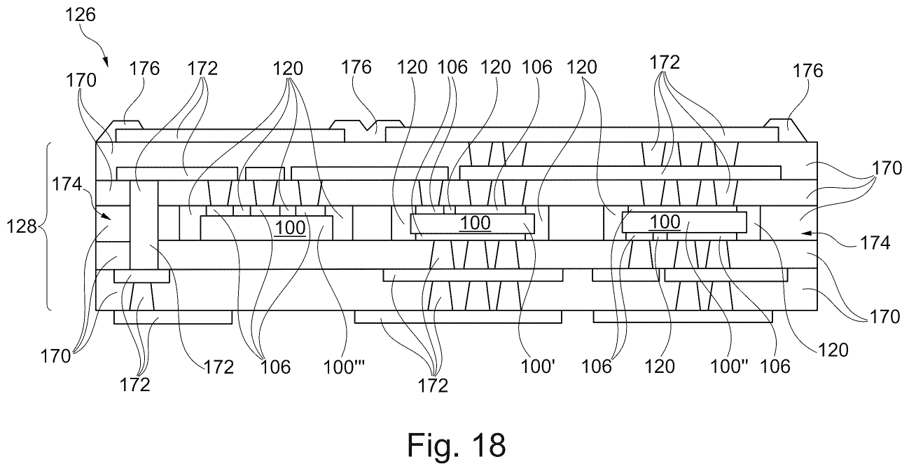

In an embodiment, the electronic component may be surface mounted on the carrier (see for example FIG. 1). For instance, such a carrier may be a leadframe structure. In another embodiment, the electronic component may be embedded in the carrier (compare for example FIG. 18). For example, a corresponding carrier may be a laminate, in particular an organic laminate.

In an embodiment, the at least one metallization structure comprises a front side metallization structure on or above the active region. Said front side metallization may allow to provide an electric connection between at least one integrated circuit element of the active region and an exterior of the electronic component. The described metallization structure, when implemented as front side metallization structure, may ensure contamination friendly and stable manufacture as well as a reliable protection against particle diffusion, stack delamination and corrosion while ensuring solderability.

In an embodiment, the at least one front side metallization structure comprises a base structure covered by the barrier structure and comprising aluminium. Such a base structure may be a thick metal pad, preferably an aluminium-based metallization, which may be in electric connection with monolithically integrated circuit elements of the semiconductor body's active region.

In an embodiment, the copper and/or aluminium structure is a finish structure. In particular, the copper and/or aluminium structure of the front side metallization may form an exterior surface of the electronic component where the electronic component can be connected in an electrically conductive fashion with another element or member, in particular by soldering. Thus, the copper and/or aluminium structure may be solderable.

In an embodiment, different sections of at least one of the at least one metallization structure are separated by the dielectric structure, wherein for example said different sections are additionally separated by a further dielectric structure, for example stacked on said dielectric structure. The dielectric structure may function as a mechanical barrier physically separating different sections of the metallization structure from each other. At the same time, the dielectric structure may be electrically insulating and may therefore also function as an electrically insulating barrier against current flow between different sections of the metallization structure and/or other elements or members. In one embodiment, the dielectric structure may be made of a single material or may be only one physical body. In another embodiment, the dielectric structure may be supplemented by at least one further dielectric structure which may be made of the same or another dielectric material and which may further refine the mechanical and electrical barrier function.

In an embodiment, the dielectric structure, and optionally a further dielectric structure, separate(s) at least one of said at least one metallization structure from a further metallization structure without said stack. Hence, the dielectric structure and optionally a further or other dielectric structure may physically separate and electrically insulate different metallization structures from each other, even if one of such metallization structures does not comprise the above-mentioned multilayer stack. This may disable an undesired flow of electric charge carriers between different metallization structures.

In an embodiment, the stack is a layer sequence. In particular, the stack may be a horizontal planar layer sequence. Alternatively, the stack may be a partially horizontal planar and partially slanted layer sequence, wherein for example a slanted portion of said layer sequence is arranged on a slanted sidewall of the dielectric structure. When embodied as a layer sequence, the barrier structure may be a barrier layer, the intermediate structure may be an intermediate layer, and the copper and/or aluminium structure may be a copper and/or aluminium layer. Such a layer sequence may be embodied as a stack of parallel layers, in particular of at least three or exactly three parallel layers. Such a layer stack may be entirely horizontal. Alternatively, such a layer stack may comprise a horizontal section and/or a slanted section, or may be curved.

In an embodiment, the dielectric structure comprises polyimide and/or an epoxy material. Other electrically insulating materials, for instance other polymers, are however possible as well.

In an embodiment, the at least one metallization structure comprises a back side metallization structure opposing the active region. When configured as back side metallization, the metallization structure may establish an electrical and/or mechanical connection of the electronic component with another member or element. The described metallization structure, when implemented as back side metallization structure, may allow connection on a rough semiconductor surface as well as a reliable protection against particle diffusion, stack delamination and corrosion while ensuring solderability.

In an embodiment, the copper and/or aluminium structure is a seed structure. When the metallization structure is embodied as a back side metallization, its copper and/or aluminium structure may be a thin seed structure, such as a seed layer, on which a thick metallic structure can be applied. The latter may comprise copper and/or aluminium as well. A seed structure, which may be applied for instance by PVD or electroless deposition, may simplify the subsequent formation of a thicker metal structure thereon, for instance by electroplating. A seed structure of copper and/or aluminium may also allow a contamination friendly etching process.

In an embodiment, the electronic component comprises a bulk metal structure, for instance made of copper, on the seed structure. Thus, when embodied as back side metallization, the metallization stack may constitute a basis for the subsequent formation of a thick bulk metal structure thereon. Copper may be a preferred material for such a metal structure.

In an embodiment, the intermediate structure is made of nickel-vanadium or nickel-silicon. Advantageously, a nickel-vanadium structure or layer has turned out as an excellent choice in terms of adhesion promotion between a titanium-based barrier structure and the copper and/or aluminium structure. At the same time, a nickel-vanadium structure or layer may provide a reliable corrosion protection. However, also other nickel-containing materials may provide an advantageous functionality of the intermediate structure in terms of adhesion promotion and corrosion protection, such as for example nickel-silicon.

In an embodiment, the barrier structure comprises titanium, wherein for example the barrier structure is made of titanium, titanium-tungsten, and/or titanium nitride. Such a titanium-based barrier structure may provide excellent properties in terms of suppressing diffusion and/or migration of particles through the metallization structure.

In an embodiment, the intermediate structure is an adhesion promoting structure. In particular, an intermediate structure comprising nickel and being preferably made of nickel-vanadium may efficiently promote adhesion between a titanium-based barrier structure on the one hand and a copper and/or aluminium structure on the other hand. Thus, delamination of the metallization stack may be reliably prevented by such an intermediate structure.

In an embodiment, the electronic component comprises a solder structure on the copper and/or aluminium structure. For instance, such a solder structure may be for example a solder bump or a solder layer. The copper and/or aluminium material of the copper and/or aluminium structure may allow to establish a solder connection between the metallization structure and another element or member. However, it may be alternatively possible to establish an electrically conductive connection between the copper and/or aluminium material and another element or member in another way than by soldering, for instance by sintering or using an electrically conductive glue.

In an embodiment, the barrier structure is a barrier layer, the intermediate structure is an intermediate layer, and/or the copper and/or aluminium structure is a copper and/or aluminium layer. In particular, the metallization structure may be a triple-layer.

In an embodiment, a thickness of the barrier structure is in a range from 50 nm to 500 nm, in particular in a range from 100 nm to 300 nm. In an embodiment, a thickness of the intermediate structure is not more than 150 nm, in particular in a range from 10 nm to 100 nm. In an embodiment, a thickness of the copper and/or aluminium structure is in a range from 10 nm to 1000 nm, in particular in a range from 50 nm to 500 nm. Hence, each of the constituents of the metallization structure may be a thin film. Thus, a tiny and compact metallization structure may be provided which provides nevertheless excellent functionality.

In an embodiment, the electronic component comprises a passivation layer, for example comprising silicon oxide and/or silicon nitride, separating at least part of at least one of the at least one metallization structure with respect to the dielectric structure. Such a passivation layer may be a thin film rather than a bulky structure, as the above-mentioned dielectric structure can be. Formation of a passivation layer may involve creation of a shielding layer which may be applied as a coating. In particular a silicon oxide and silicon nitride passivation layer may reliably separate metallization structure with respect to dielectric structure.

In an embodiment, the barrier structure has a larger lateral extension than a smaller lateral extension of the intermediate structure and the copper and/or aluminium structure. In other words, the barrier structure may extend over a larger surface region than the intermediate structure and the copper and/or aluminium structure. By taking this measure, the barrier effect may be spatially extended. However, in another embodiment, the barrier structure, the intermediate structure and the copper and/or aluminium structure may extend over the same (or at least substantially the same) surface region, so that they can be patterned together. This may simplify the manufacturing process.

In an embodiment, the carrier comprises one of the group consisting of a leadframe structure, and a ceramic sheet with metallic layers on both opposing main surfaces thereof. For example, the carrier is a leadframe structure (for instance made of copper). Preferably, such a leadframe-type carrier comprises a die paddle or die pad, on which the electronic component is mounted. Furthermore, such a leadframe-type carrier may comprise at least one lead, preferably a plurality of leads. A leadframe structure may be a metal structure of the package that carries signals from the electronic component to the outside, and/or in opposite direction. It is however also possible that such a carrier is a DAB (Direct Aluminium Bonding) substrate, a DCB (Direct Copper Bonding) substrate, etc. Moreover, the carrier may also be configured as Active Metal Brazing (AMB) substrate. Also at least part of the carrier may be encapsulated by an encapsulant, together with the electronic component.

In an embodiment, the package comprises a solder structure between the carrier and at least one of the at least one metallization structure of the electronic component. For instance, such a solder structure may be a solder bump or solder layer. For example, the solder structure may comprise tin.

In an embodiment, the package comprises a clip connected with at least one of the at least one metallization structure by a solder structure. Additionally or alternatively, the package comprises a bond wire connected with at least one of the at least one metallization structure. Thus, the package may comprise at least one electrically conductive coupling element electrically coupling the electronic component with another element or member, such as the carrier. Such an electrically conductive coupling element may be a clip, a bond wire or a bond ribbon. A clip may be a flat or curved electrically conductive body accomplishing an electric connection with a high connection area to an upper main surface of a respective electronic component. Additionally or alternatively to such a clip, it is also possible to implement one or more other electrically conductive interconnect bodies in the package, for instance a bond wire and/or a bond ribbon connecting the electronic component with the die pad and/or a lead or connecting different pads of an electronic component.

In an embodiment, the method comprises forming at least one of the barrier structure, the intermediate structure, and/or the copper and/or aluminium structure by physical vapor deposition (PVD). Preferably, each of said three structures may be formed by PVD, which may simplify the manufacturing process.

In an embodiment, the method comprises patterning at least two of the barrier structure, the intermediate structure, and the copper and/or aluminium structure in common. Also such a common patterning may contribute to a simple manufacturing process.

In an embodiment, the method comprises patterning the barrier structure, the intermediate structure, and/or the copper and/or aluminium structure by wet chemically etching. In view of the construction of the metallization structure as described herein, a contamination friendly etching process may be possible.

In an embodiment, the electronic component is configured as a power semiconductor chip. Thus, the electronic component (such as a semiconductor chip) may be used for power applications for instance in the automotive field and may for example have at least one integrated insulated-gate bipolar transistor (IGBT) and/or at least one transistor of another type (such as a MOSFET, a JFET, a HEMT, etc.) and/or at least one integrated diode. Such integrated circuit elements may be manufactured for instance in silicon technology or based on wide-bandgap semiconductors (such as silicon carbide, gallium nitride). A semiconductor power chip may comprise one or more field effect transistors, diodes, inverter circuits, half-bridges, full-bridges, drivers, logic circuits, further devices, etc.

In an embodiment, the package is configured as power package. A power package may be a package comprising at least one power chip as electronic component. Thus, the package may be configured as power module, for instance molded power module such as a semiconductor power package. For instance, an exemplary embodiment of the package may be an intelligent power module (IPM). Another exemplary embodiment of the package is a dual inline package (DIP).

In an embodiment, the package comprises a solder layer at a metallization structure. For example, the solder layer has a thickness of less than 10 μm, in particular a thickness in a range from 1 μm to 5 μm. Correspondingly, the manufacturing method may comprise connecting the electronic component by soldering, in particular by diffusion soldering. Such a thin layer of solder may be used to connect the electronic component with another element or member by diffusion soldering.

In an embodiment, the package comprises an encapsulant encapsulating at least part of the electronic component. In the context of the present application, the term “encapsulant” may particularly denote a substantially electrically insulating material surrounding at least part of an electronic component and part of a carrier to provide mechanical protection, electrical insulation, and optionally a contribution to heat removal during operation. In particular, said encapsulant may be a mold compound. A mold compound may comprise a matrix of flowable and hardenable material and filler particles embedded therein. For instance, filler particles may be used to adjust the properties of the mold component, in particular to enhance thermal conductivity. As an alternative to a mold compound (for example on the basis of epoxy resin), the encapsulant may also be a potting compound (for instance on the basis of a silicone gel).

For example, a package according to other exemplary embodiments may be configured as one of the group consisting of a leadframe connected power module, a Control integrated power system (CIPOS) package, a Transistor Outline (TO) package, a Quad Flat No Leads Package (QFN) package, a Small Outline (SO) package, a Small Outline Transistor (SOT) package, and a Thin Small Outline Package (TSOP) package. For example, the package may be implemented in a “CIPOS™ Mini” configuration or a “TO-247” configuration of the applicant Infineon Technologies AG. Also packages for sensors and/or mechatronic devices are possible embodiments. Moreover, exemplary embodiments may also relate to packages functioning as nano-batteries or nano-fuel cells or other devices with chemical, mechanical, optical and/or magnetic actuators. Therefore, the package according to an exemplary embodiment is fully compatible with standard packaging concepts and appears externally as a conventional package, which is highly user convenient.

In an embodiment, at least one further electronic component in mounted on the carrier. Thus, a plurality of electronic components may be mounted side by side on the same carrier. For instance, at least two electronic components may be mounted on one carrier.

As substrate or wafer forming the basis of the electronic components, a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized.

According to an exemplary embodiment, a semiconductor chip-type electronic component may be provided with a semiconductor body in which an active region may be formed. A stack-type metallization structure may be formed on or above the active region as front side metallization and/or facing away from the active region as back side metallization. Such a stacked metallization structure may comprise a barrier structure for inhibiting diffusion or migration, an intermediate structure including nickel and providing an adhesion promoting and/or corrosion suppressing function, and a copper and/or aluminium structure which may simplify establishing a solder connection or deposition of a metal.

When the stacked metallization structure is embodied as front side metallization according to a first aspect of the disclosure, an optional dielectric structure (which may for example comprise polyimide and/or another polymer) may be connected sideways of the stacked metallization structure as a physical and electrically insulating barrier. This may improve the electrical reliability of the package, since undesired electrically conductive paths involving the metallization structure may be prevented by said sidewall coverage. The described configuration of the front side metallization may allow to carry out a contamination friendly etching process during manufacture while ensuring a stable process without the risk of excessive contamination.

When embodied as back side metallization according to a second aspect of the disclosure, it may be a preferred option that the metallization structure is formed on a rough semiconductor body having a quite high roughness Ra of at least 1 μm. This may simplify processing, since the provision of a smooth semiconductor surface or the execution of a planarizing or smoothing process as a basis for a back side metallization structure may be dispensable.

Referring to said first aspect, a conventional silver structure as a protection layer may be substituted by Al, Cu or AlCu in a chip front side metallization stack. Such a chip front side metallization stack may comprise an Al- and/or Cu-based layer which may be a top or finish layer. Furthermore, the metallization stack may comprise a Ti-based barrier, and the metallization stack may advantageously comprise a NiV interlayer.

In the following, embodiments of said first aspect will be explained in further detail.

In such an embodiment, a structured NiV/Cu or NiV/Al metallization may be provided on a chip front side for soldering.

Conventionally, solderable front side metallizations may be realized by a three-layer chip front side metallization utilizing a stack of Ti/NiV/Ag. This stack may cause manufacturing stability and contamination challenges or quality issues while structuring the layers. Thus, Ti/NiV/Ag may be replaced by very thick solderable Cu layers. These thick Cu metallization may cause wafer and chip bow challenges which may require a back side compensation Cu layer. This may increase the manufacturing effort.

According to exemplary embodiments, structurable NiV/Cu or NiV/Al metallization stacks may be formed on Ti-based barriers (for instance comprising Ti, TiW). By replacing Ag (in a three-layer solderable front side metallization Ti/NiV/Ag) as protection layer by Cu and/or Al, a contamination friendly etching process can be chosen. The Cu and/or Al layer may be resolved later in a soldering interconnect process or may represent a surface for wire bonding.

Exemplary applications of exemplary embodiments are transistor chips like SFET discretes, such as Direct-FETs, or Source Down-FETs.

Referring to said second aspect, corrosion robustness of a chip-embedded package may be ensured by improving adhesion of Ti, on the one hand, and Cu and/or Al, on the other hand, using a nickel-containing interlayer, preferably a NiV layer. Such a NiV layer may be deposited between layers of Cu and/or Al, on the other hand, and Ti, on the other hand. Advantageously, the addition of a NiV layer may promote adhesion between the Cu and/or Al layer and the Ti layer. Preferably, the layer of NiV may be deposited using PVD after the deposition of Ti using PVD and before a PVD of Cu- and/or Al-seed is performed on the back side metal stack. A wet chemical etching may be performed on the Cu and/or Al, NiV and Ti layers once Cu and/or Al deposition and lithography is completed. NiV may be etched with the same chemistry as the Cu and/or Al layer, wherein the benefit of strong adhesion between Cu and/or Al, on the one hand, and, on the other hand, Ti, due to the NiV layer may result in corrosion and delamination robustness of the back side metallization, which may provide a protection against harsh humidity stress.

In the following, embodiments of said second aspect will be explained in further detail.

In particular, a corrosion robustness improvement of a Ti to Cu (or Al) interface for chip-embedded packages may be achieved by a Ni based adhesion interlayer.

Conventionally, corrosive delamination of a Ti to Cu interface may occur in packages as visible in humidity stress tests.

In an embodiment, a Ti/NiV/Cu (and/or Al) back side metal stack may be implemented. NiV may improve adhesion of Ti to Cu and may make the metal stack corrosion robust. More specifically, a NiV interlayer may be formed by PVD after Ti PVD and prior Cu-seed PVD on a back side metallization. All targets may be available on the same tool and may be therefore simple. After Cu deposition and lithography, the Cu, NiV and Ti layer may be wet chemically etched. NiV may be etched with the same chemistry as the Cu layer. Also this etch process may be technically simple. The NiV may act as an adhesion promoter layer and may avoid void formation and interface degradation during stress testing and other thermal budgets.

In particular, an in situ-PVD NiV adhesion layer may be formed to improve adhesion between Cu and Ti. Such a metallization structure may reveal full corrosion robustness even under harsh humidity stress conditions.

For example, a NiV adhesion layer may be formed by in situ-PVD of Ti-based barriers with Ni/V-based adhesion layers prior Cu (seed or thick PVD) deposition. For example, the NiV layer may be realized with a thickness of 75 nm. Such a Ni/V-based layer may also act as microstructural mechanical stress compensator. Moreover, Ni and/or V may act as dopant within a Ti-based metallization (like a corrosion robust Ti-alloy). NiV may prevent S and Cl contaminants from reaching the corrosion sensitive Ti-layer for preventing Cl and S triggered corrosion. Furthermore, NiV may prevent Si diffusion through a Ti-based barrier.

Advantageously, there are substantially no limitations what concerns an implemented package concept. Thus, exemplary embodiments may be implemented for chip-embedded devices and for molded and soldered devices. In an embodiment, NiV may act as adhesion layer rather than as soldering material and may thus be provided with thin layer thickness. Furthermore, there is basically no restriction with regard to the positioning of a Ti—X/Ni-V-X/Cu metallization on chips. Thus, an implementation for Cu-based front side metallization (in particular for lateral devices) and back side metallization may be possible. Advantageously, exemplary embodiments may be implemented for all kinds of Ti-based metallization (such as Ti, TiW). Furthermore, there is basically no restriction whether the metallization is structured or unstructured.

What concerns adhesion layer materials, NiV is a particularly advantageous choice as low complexity implementation with excellent functionality. Ni or Al or V may be used as corrosion robust alloying elements.

In particular, an exemplary embodiment provides a solderable back side metallization stack with Ti/NiV/Cu sequence.

A conventional chip back side metallization with an unstructured Ti/NiV/Ag stack does not fulfill thermal and thermomechanical requirements for many power-semiconductor applications. In another conventional approach, a used thick solderable TiW/Cu layer may face corrosion issues.

According to an exemplary embodiment, a structured Ti/NiV/Cu metallization stack may be provided with a thin Ti barrier, a thin NiV adhesion layer and a thick Cu layer (wherein “thin” may mean in this context in particular 50 nm to 200 nm, and “thick” may mean in this context in particular 5 μm to 20 μm). Advantageously, a NiV layer may be introduced into a Ti/Cu stack to solve thermal, thermomechanical and quality requirements.

More specifically, exemplary embodiments may implement a thick three-layer structured back side metallization comprising or consisting of Ti, NiV and Cu on a power-MOSFET chip back side. Advantageously, a roughened Si based substrate may be used. Optionally, such a stack may also be applied on smooth Si-based substrates. The Cu may have a thickness of 5 μm to 20 μm, NiV may have a thickness of 50 nm to 100 nm, and Ti may have a thickness of 10 nm to 300 nm, for instance 200 nm.

Advantageously, the electronic component may be in particular a vertical power-MOSFET.

Exemplary embodiments may comprise in particular one or more of the following constituents (wherein different constituents and different thicknesses as well as different manufacturing methods may be possible in other embodiments):
Al-based metallization (AlCu, AlSiCu, Al): 2-10 μm, for instance 3.5 μm; PVD (physical vapor deposition)
Ti-based barrier (Ti, TiN, TiW): 100-300 nm; PVD
NiV adhesion layer (NiV or NiSi): 10 nm to 100 nm, in particular not more than 100 nm (for example target thickness 75 nm); PVD
Cu metallization thin on front: 100-500 nm; PVD
Cu metallization thick on the back: 5-15 μm; ECD (electrochemical deposition), but with thin Cu-seed in PVD process)
Al metallization thin on front side in barrier/NiV adhesion layer/Al stack: 50-300 nm
Dielectric 1 (polyimide): 5-10 μm
Dielectric 2 (polyimide, epoxy, etc.): 5-10 μm
Passivation (silicon oxide plus silicon nitride): 300 nm-2 μm

For the back side roughness Ra, values of approximately 2 μm or more may be possible (for example SZ 2-3 μm peak to peak; Sa=250 nm)

More specifically, roughness with different lateral scales may be superimposed, such as waviness in the 10-100 μm range and a fine roughness in the μm range.

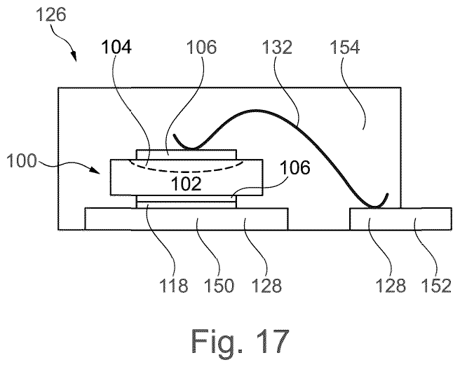

FIG. 1 illustrates a cross-sectional view of part of a package 126 with an electronic component 100 surface mounted on a carrier 128 according to an exemplary embodiment. FIG. 1 only shows part of package 126. Other constituents of package 126 may be taken from FIG. 17, such as a carrier 128 or an optional encapsulant 154.

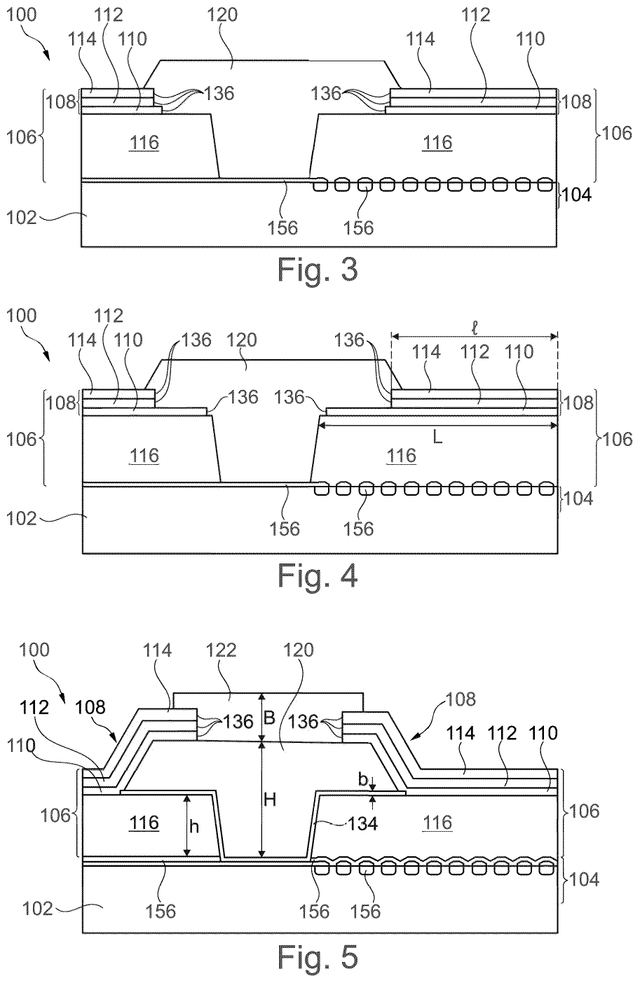

As shown, package 126 comprises an electronic component 100, which is here embodied as semiconductor die. The electronic component 100 comprises a semiconductor body 102, such as a silicon substrate. As shown as well in FIG. 1, optional back end of the line (BEOL) structures 156 may be arranged at a top side of the semiconductor body 102. In an active region 104 in a front side surface portion of the semiconductor body 102, one or more integrated circuit elements (for instance a field-effect transistor, a diode, etc.) may be integrated, in particular monolithically integrated. Furthermore, FIG. 1 shows two front side metallization structures 106 arranged side-by-side and laterally separated from each other by a dielectric structure 120. Each of the illustrated metallization structures 106 may be located on or above the active region 104 and may comprise a layer stack 108, which will be described in further detail referring to FIG. 2, FIG. 3, etc.

In the cross-sectional view of FIG. 1, the dielectric structure 120 is mushroom shaped and is connected on opposing sidewalls thereof with a respective sidewall 136 of the respective stack 108. Thus, the electrically insulating dielectric structure 120, which may be made for instance of polyimide, may spatially separate the front side metallization structures 106 from each other and may also guarantee their electric isolation from each other.

As can be taken from FIG. 1 as well, each respective front side metallization structure 106 comprises a base structure 116, which may be a metallization pad, below the layer stack 108, so that the base structure 116 is arranged between the active region 104 and the layer stack 108. For example, the base structure 116 may be significantly thicker than the stack 108 and may comprise for example aluminium or may be aluminium-based (for instance may comprise an aluminium alloy, such as AlCu). For instance, a thickness h of the base structure 116 may be in a range from 1 μm to 10 μm, in particular 2 μm to 5 μm.

According to FIG. 1, a surface portion including a sidewall of the base structures 116 and a surface portion including a sidewall of the stacks 108 are connected to respective sidewall sections of the dielectric structure 120. For instance, a thickness H of the dielectric structure 120 may be in a range from 3 μm to 12 μm, in particular 6 μm.

Still referring to FIG. 1, a bond wire 132 is shown which can be connected with the layer stack 108 of the front side metallization structure 106 shown on the left-hand side of FIG. 1. Thus, stack 108 on the left-hand side of FIG. 1 may be a wire bondable pad which can be connected with bond wire 132 even without solder layer in between. Moreover, a clip 130 may be connected by a solder structure 118 to the layer stack 108 of the front side metallization structure 106 shown on the right-hand side of FIG. 1. Hence, stack 108 shown on the right-hand side of FIG. 1 may be a solderable pad.

The electronic component 100 according to FIG. 1 may be a field-effect transistor chip. The metallization structure 106 shown on the left-hand side of FIG. 1 may form a gate pad. The metallization structure 106 shown on the right-hand side of FIG. 1 may form a source pad. The source pad may have a larger area than the gate pad. The drain pad is not visible in FIG. 2 and may be arranged on the opposing main surface of the semiconductor body 102 than the source pad and the gate pad. In such a configuration, the electronic component 100 may experience a vertical current flow during operation.

FIG. 2 illustrates an image of a stack 108 of a front side metallization structure 106 of an electronic component 100 according to an exemplary embodiment.

The illustrated metallization structure 106 has a semiconductor-sided base structure 116 which may be embodied as an aluminium-based metallization. Stack 108 is arranged on the base structure 116 and is embodied according to FIG. 2 as a three-layer stack.

As shown, stack 108 may comprise bottom-sided barrier structure 110, intermediate structure 112 thereon and copper and/or aluminium structure 114 on top. Generally, a thickness d1 of the barrier structure 110 may be in a range from 50 nm to 500 nm. A thickness d2 of the intermediate structure 112 may be not more than 150 nm. A thickness d3 of the copper and/or aluminium structure 114 may be in a range from 10 nm to 1000 nm.

Now referring to the specific example of FIG. 2, bottom-sided barrier structure 110 is formed on the base structure 116, intermediate structure 112 is formed on the barrier structure 110, and copper and/or aluminium structure 114 is formed on the intermediate structure 112. The barrier structure 110 can be embodied as titanium-based barrier and may have for example a thickness d1 in the range from 100 nm to 300 nm. The intermediate structure 112 can be embodied as NiV interlayer and may have a thickness d2 of not more than 100 nm, for example 75 nm. Advantageously, the intermediate structure 112 can have a very small thickness d2 which simplifies a patterning process. The copper and/or aluminium structure 114 can be for example a copper finish (and/or an aluminium finish) and may have a thickness d3 of not more than 500 nm. The barrier structure 110 may function as a barrier against particle diffusion or migration between the base structure 116 and the intermediate structure 112. The intermediate structure 112 or interlayer may promote adhesion between the barrier structure 110 and the copper and/or aluminium structure 114 and may also suppress corrosion and/or oxidation. The copper and/or aluminium structure 114 may provide a solderable interface and may avoid oxidation of the intermediate structure 112. Thus, the stack 108 of FIG. 2 may be solderable, for instance by solder paste provided on the copper and/or aluminium structure 114.

Each of the barrier structure 110, the intermediate structure 112, and the copper and/or aluminium structure 114 may be formed by physical vapor deposition (PVD). During manufacture, the barrier structure 110, the intermediate structure 112, and the copper and/or aluminium structure 114 may be patterned in common, for instance using a common mask and etching process. Said patterning of the barrier structure 110, the intermediate structure 112, and the copper and/or aluminium structure 114 may be executed by wet chemically etching.

FIG. 3 illustrates a cross-sectional view of an electronic component 100 according to an exemplary embodiment. The electronic component 100 according to FIG. 3 corresponds to the illustration in FIG. 1 but shows a detailed construction of the stacks 108 of the front side metallization structures 106. According to FIG. 3, a three-layer stack 108 may be formed on an aluminium-based pad metallization in form of base structure 116 for all pads. As in FIG. 1, pads are provided for a wire bond interconnection on copper as well as for a soldering interconnection on copper/nickel-vanadium.

As shown in FIG. 3, each of the two stacks 108 (the left corresponding to a gate pad and the right corresponding to a source pad) have layer-type barrier structure 110 on the bottom-sided aluminium-based base structure 116, layer-type intermediate structure 112 on the barrier structure 110, and layer-type copper and/or aluminium structure 114 on the intermediate structure 112.

Preferably, the barrier structure 110 may be made of titanium, titanium-tungsten, or titanium nitride to function as a diffusion barrier. Advantageously, the intermediate structure 112 is made of nickel-vanadium or nickel-silicon to act as an adhesion promoting structure and for inhibiting corrosion. Moreover, the copper and/or aluminium structure 114 is a finish structure which may comprise Cu, Al or AlCu, which may be solderable and which may provide an oxidation or corrosion protection for the intermediate structure 112.

According to FIG. 3, each of the stacks 108 is a horizontal planar three-layer sequence. Each of the barrier structure 110, the intermediate structure 112 and the copper and/or aluminium structure 114 have substantially the same horizontal extensions on the respective base structure 116 and may thus be patterned together by wet etching process. This may simplify the manufacturing process.

Dielectric structure 120, which may comprise for example polyimide, is connected to both a sidewall 136 of the stack 108 on the left-hand side and a sidewall 136 of the stack 108 on the right-hand side. Thereby, the metallization structures 106 or different sections of a metallization structure 106 on the left-hand side and on the right-hand side of the dielectric structure 120 are physically separated and electrically isolated with respect to each other.

FIG. 4 illustrates a cross-sectional view of an electronic component 100 according to another exemplary embodiment. According to FIG. 4, barrier structuring may be independent of interlayer and finish structuring.

The embodiment of FIG. 4 differs from the embodiment of FIG. 3 in particular in that, according to FIG. 4, a respective barrier structure 110 has a larger lateral extension L than a smaller lateral extension 1 of an assigned intermediate structure 112 and an assigned copper and/or aluminium structure 114. Thus, the barrier structure 110 may be patterned (in particular by etching) separately from a patterning process (in particular by etching) carried out together for the intermediate structure 112 and the copper and/or aluminium structure 114. By covering the entire upper main surface of the base structure 116 with the barrier structure 110 according to FIG. 4 (rather than only covering part thereof, as in FIG. 3), diffusion and/or migration processes may be prevented even more reliably according to FIG. 4.

FIG. 5 illustrates a cross-sectional view of an electronic component 100 according to another exemplary embodiment. This embodiment provides a three-layer stack above a passivation as well as an aluminium-based metallization.

The embodiment of FIG. 5 differs from the embodiment of FIG. 3 in particular in that, according to FIG. 5, the different sections of the metallization structure 106 are separated not only by the dielectric structure 120, but additionally by a further dielectric structure 122 which is stacked on said dielectric structure 120. According to FIG. 5, the dielectric structure 120 and the further dielectric structure 122 separate different metallization structures 106 or different sections of a metallization structure 106. For example, dielectric structure 120 may be made of polyimide material and further dielectric structure 122 may be made of polyimide and/or an epoxy material. The stacking of further dielectric structure 122 on dielectric structure 120 increases the height of the insulating barrier between the different metallization structures 106 and prevents leakage currents. For instance, a thickness B of the further dielectric structure 122 may be in a range from 6 μm to 10 μm.

Moreover, in contrast to FIG. 3 and FIG. 4, each of the stacks 108 of FIG. 5 is embodied as a partially horizontal planar and partially slanted layer sequence. As shown, a respective slanted portion of said layer sequence is arranged on a slanted sidewall of the dielectric structure 120 and a horizontal planar portion of said layer sequence connects with a vertical sidewall of the further dielectric structure 122.

FIG. 5 also shows a passivation layer 134, for example comprising silicon oxide and silicon nitride, separating the base structures 116 of the metallization structures 106 on a bottom side of the passivation layer 134 with respect to the dielectric structure 120 on a top side of the passivation layer 134. Moreover, the passivation layer 134 may also separate the semiconductor body 102 with respect to the dielectric structure 120. For example, the passivation layer 134 may have a thickness b in a range from 100 nm to 1000 nm, in particular in a range from 300 nm to 500 nm. The passivation layer 134 may constitute a shielding layer and may be applied by coating or as a thin-film to reliably separate the base structure 116 with respect to the dielectric structure 120. Although not each and every embodiment illustrated in the figures shows a passivation layer 134, a passivation layer 134 may be optionally present in each and every of said embodiments.

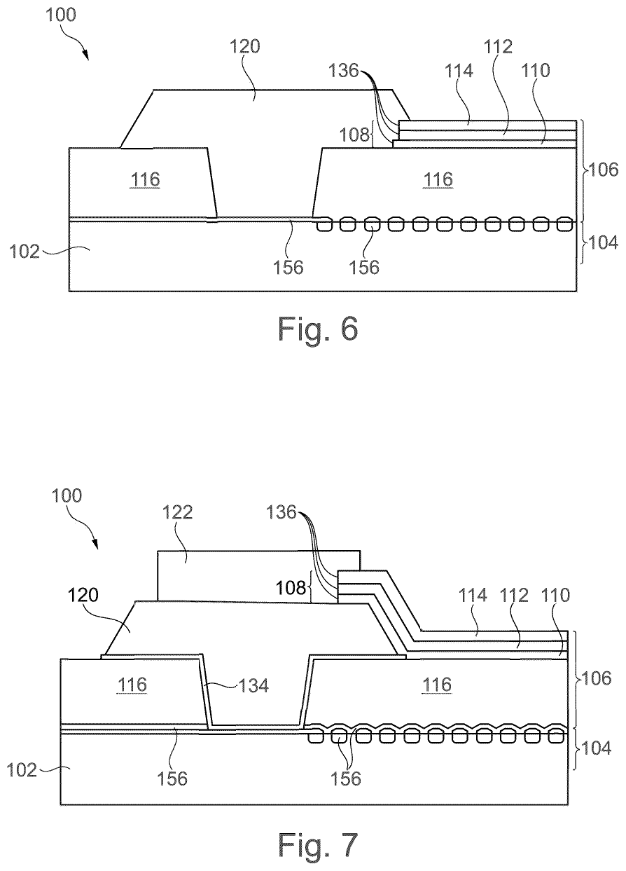

FIG. 6 illustrates a cross-sectional view of an electronic component 100 according to another exemplary embodiment. The embodiment of FIG. 6 has a three-layer stack for a solder interconnect pad only.

The embodiment of FIG. 6 differs from the embodiment of FIG. 3 in particular in that, according to FIG. 6, in addition to the base structure 116 covered by stack 108, a further base structure 116 is provided without such a stack 108 thereon. While the base structure 116 covered by stack 108 can form again a source pad, the base structure 116 without stack 108 may form a gate pad according to FIG. 6. Thus, two metallization structures 106 or sections of a metallization structure 106 may be provided, one comprising a base structure 116 only and the other one comprising a base structure 116 with stack 108 thereon.

FIG. 7 illustrates a cross-sectional view of an electronic component 100 according to another exemplary embodiment.

The embodiment of FIG. 7 differs from the embodiment of FIG. 5 in particular in that, according to FIG. 7, stack 108 on the left-hand side of FIG. 5 is omitted in FIG. 7. Thus, in addition to the base structure 116 covered by stack 108, a further base structure 116 is provided without such a stack 108 in FIG. 7. While the base structure 116 covered by stack 108 can form again a source pad, the base structure 116 without stack 108 may form a gate pad according to FIG. 7. Thus, also in the presence of dielectric structure 120 and further dielectric structure 122, two metallization structures 106 or sections of a metallization structure 106 may be provided, one comprising a base structure 116 only and the other one comprising a base structure 116 with stack 108 thereon.

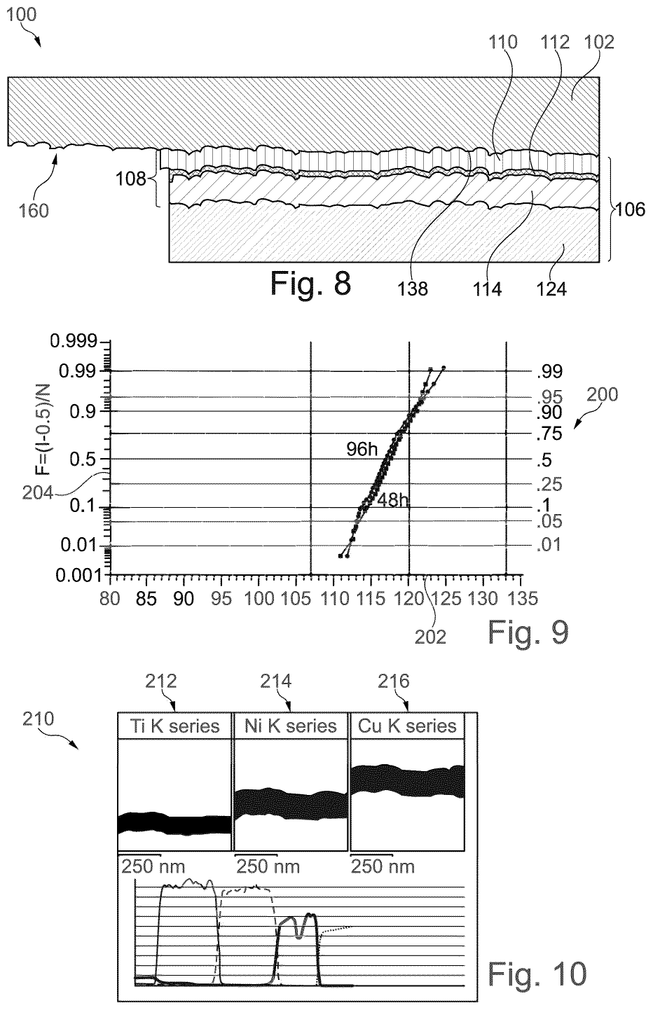

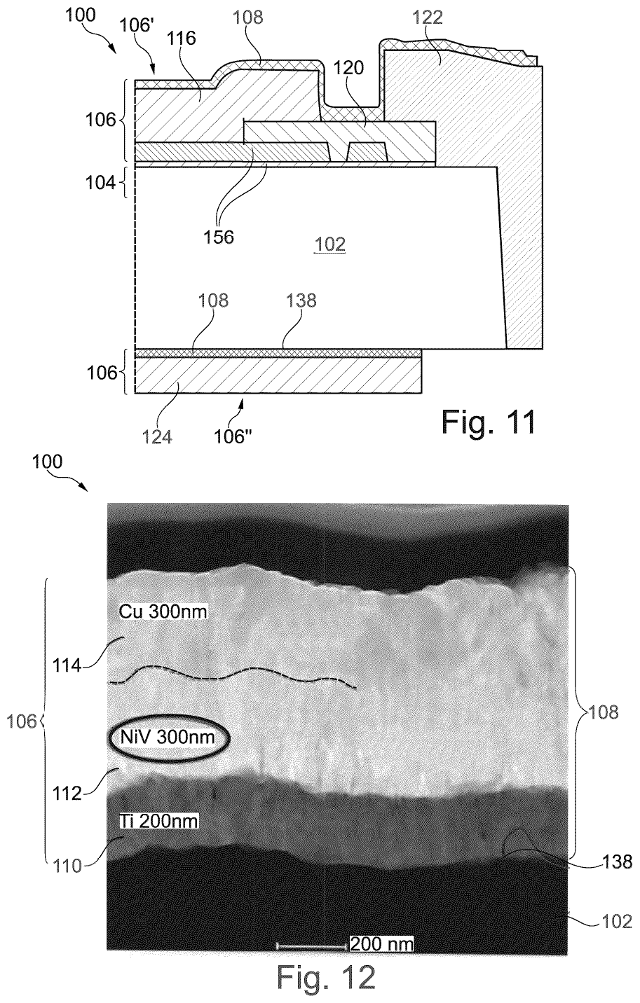

FIG. 8 illustrates a cross-sectional view of an electronic component 100 according to another exemplary embodiment. Also such an electronic component 100 can form part of a package 126, as shown for instance in FIG. 11 or FIG. 17.

The electronic component 100 shown in FIG. 5 may be a semiconductor die, for instance a power semiconductor die. The electronic component 100 may comprise a semiconductor body 102, which may be a silicon substrate. Back side 160 of semiconductor body 102 may be opposing to another side of the semiconductor body 102 in which an active region may be formed (compare reference sign 104 in FIG. 11, FIG. 17 or FIG. 1).

As shown in FIG. 8, a back side metallization structure 106 is provided on the back side 160 and thus on an opposing side of the semiconductor body 102 with respect to the active region 104. Said back side metallization structure 106 comprises a layer stack 108 on a rough surface of the semiconductor body 102. Stack 108 has a semiconductor-sided barrier structure 110, an intermediate structure 112 on the barrier structure 110, and a copper and/or aluminium structure 114 on the intermediate structure 112. In the shown embodiment, barrier structure 110 can be embodied as a titanium-based barrier layer (for instance having a thickness of 200 nm and being manufactured by physical vapor deposition, PVD). In the illustrated embodiment, the intermediate structure 112 can be embodied as a nickel and vanadium-based adhesion promoting layer (for example having a thickness below 100 nm and being formed by PVD). Furthermore, the copper and/or aluminium structure 114 may be a copper, an aluminium or a copper-aluminium alloy seed layer (for instance having a thickness of 300 nm and being formed by PVD). As shown as well in FIG. 8, a bulk metal structure 124, for instance made of copper, aluminium or a copper-aluminium alloy, may be formed on the seed structure, for instance by electroplating. A thickness of the bulk metal structure 124, which may be formed for example by galvanic plating, may be for example 10 μm.

Still referring to FIG. 8, a surface 138 on the back side 160 of the semiconductor body 102 on which the metallization structure 106 (more precisely the barrier structure 110 of the metallization structure 106) is arranged has a roughness Ra of at least 1 μm, for example a roughness Ra of at least 2 μm or of at least 3 μm. Highly advantageously, the back side metallization structure 106 may be directly formed on such a rough back side 160 of the semiconductor body 102 without compromising on the barrier effect, the adhesion promoting effect, and the corrosion and oxidation protection effect of the constituents of the three-layer stack 108. Furthermore, formation of a thick bulk metal structure 124 may be carried out with high quality despite of the high roughness Ra of at least 1 μm on the back side 160 of the semiconductor body 102. These advantages may be achieved without necessarily executing a surface smoothing or planarizing process before applying the metallization structure 106.

However, in an alternative approach, it may be possible to smooth the back side 160 of the semiconductor body 102 prior to applying the metallization structure 106.

FIGS. 9 and 10 illustrate diagrams 200, 210 showing a characteristic of an electronic component 100 according to exemplary embodiments. In particular, the provision of a (preferably in situ-PVD) nickel-vanadium adhesion layer may improve adhesion between copper and titanium and may provide full corrosive robustness against harsh humidity stress conditions.

Referring to FIG. 9, a diagram 200 is shown which has an abscissa 202 along which an overcurrent protection value (in Ampere) is plotted. Along an ordinate 204, a probability parameter F is plotted. It can be seen from diagram 200 that a back side metallization comprising a titanium/nickel-vanadium/copper stack shows low shift of the probability parameter after 96 hours for a HAST (highly accelerated stress test) configuration at 130° C.

Referring to FIG. 10, a diagram 210 is shown which indicates that the individual layers or sub-structures of stack 108 of a back side metallization structure 106 show well-defined properties. This is true for a titanium component (see reference sign 212), for a nickel component (see reference sign 214), and for a copper component (see reference sign 216).

FIG. 11 illustrates a cross-sectional view of an electronic component 100 according to another exemplary embodiment. In particular, FIG. 11 shows a front side metallization structure 106′ (corresponding to FIG. 1 to FIG. 7) and a back side metallization structure 106″ (corresponding to FIG. 8, FIG. 12 to FIG. 16).

FIG. 12 illustrates an image of a stack 108 of a back side metallization structure 106 of an electronic component 100 according to an exemplary embodiment.

Stack 108 of FIG. 12 comprises barrier structure 110 (here embodied as 200 nm thick titanium layer) on a rough surface of semiconductor body 102, intermediate structure 112 (here embodied as 300 nm thick nickel-vanadium layer) on barrier structure 110 and copper and/or aluminium structure 114 (here embodied as 300 nm thick copper layer) on intermediate structure 112. In particular, the intermediate structure 112 provides excellent properties by providing an adhesion promoting function and suppressing corrosion.

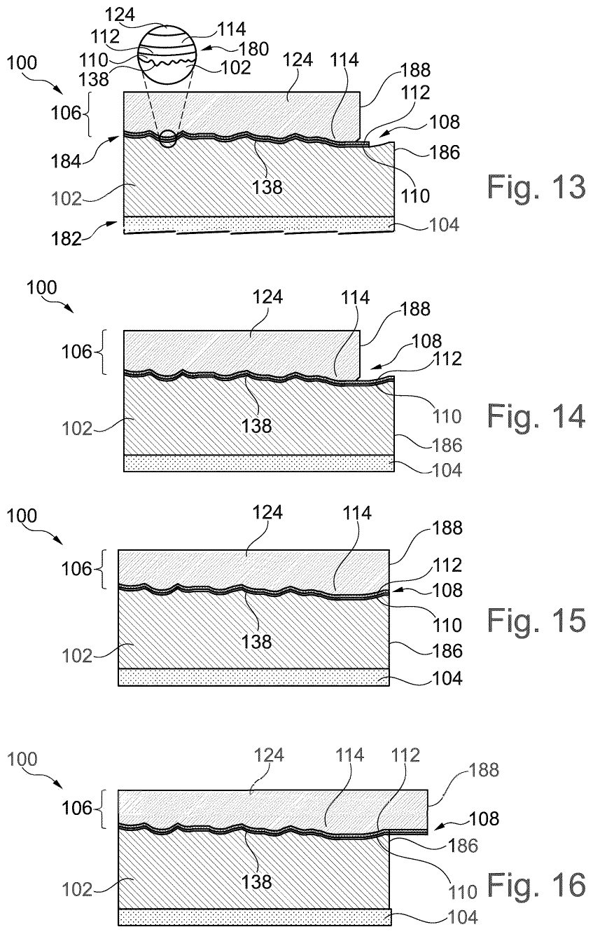

FIG. 13 illustrates a cross-sectional view of an electronic component 100, embodied as silicon chip, according to another exemplary embodiment.

This electronic component 100 has a semiconductor body 102 with a smooth front side 182 where an active region 104 is formed. Moreover, the semiconductor body 102 has a rough back side 184 opposing the front side 182. FIG. 13 shows a back side metallization structure 106 directly on the rough back side 184. A sidewall of the semiconductor body 102 is shown with reference sign 186.

The active region 104 may correspond to an active power MOSFET area and may be covered by a front side metallization structure (not shown in detail in FIG. 13).

The back side metallization structure 106 of FIG. 13 has a construction which can be taken from a detail 180. On the rough surface 138 of the semiconductor body 102, layer stack 108 is formed which comprises titanium-based barrier layer 110, nickel-vanadium-based intermediate structure 112 and copper seed-type copper and/or aluminium structure 114. A bulk metal structure 124 of thick structured copper may be formed on seed copper and/or aluminium structure 114. A sidewall of the back side metallization structure 106 is shown with reference sign 188.

FIG. 13 shows an embodiment with exposed structured barrier and adhesion promoting layer.

FIG. 14 illustrates a cross-sectional view of an electronic component 100 according to another exemplary embodiment.

The embodiment of FIG. 14 differs from the embodiment of FIG. 13 in particular in that, according to FIG. 14, an exposed unstructured barrier and adhesion promoting layer is provided. Since barrier and adhesion promoting layer are unstructured according to FIG. 14, the exposed barrier and adhesion layer extends up to the chip edge according to FIG. 14.

FIG. 15 illustrates a cross-sectional view of an electronic component 100 according to another exemplary embodiment.

The embodiment of FIG. 15 differs from the embodiment of FIG. 14 in particular in that, according to FIG. 15, the backside metallization structure 106 is unstructured. Hence, the unstructured back side metallization of FIG. 15 extends to the chip edge.

FIG. 16 illustrates a cross-sectional view of an electronic component 100 according to another exemplary embodiment.

The embodiment of FIG. 16 differs from the embodiment of FIG. 14 in particular in that, according to FIG. 16, the backside metallization structure 106 is unstructured. According to FIG. 16, the backside metallization structure 106 extends beyond the chip edge so that also the copper material extends beyond the chip edge.

FIG. 17 illustrates a cross-sectional view of a package 126 with an electronic component 100 according to an exemplary embodiment.

The illustrated package 126 comprises a carrier 128 which can be embodied as a leadframe structure. The carrier 128 comprises a die pad 150 and a lead structure 152 comprising leads. An electronic component 100, as the one shown in FIG. 1, FIG. 3 to FIG. 8 or FIG. 13 to FIG. 16 may be mounted on the die pad 150 of the carrier 128.

A front side metallization structure 106 on the upper main surface of the electronic component 100 is electrically coupled with the lead structure 152 of the carrier 128 by a bond wire 132. Additionally or alternatively to a bond wire 132, the package 126 may comprise also another electrically conductive connection element, such as a clip (not shown in FIG. 17). A back side metallization structure 106 on the lower main surface of the electronic component 102 may be connected with the die pad 150 of the carrier 128 by a solder structure 118.

The electronic component 100 and part of the carrier 128 may be encapsulated by an encapsulant 154, such as a mold compound.

However, other package architectures than the one shown in FIG. 17 are possible in other embodiments.

FIG. 18 illustrates a cross-sectional view of a package 126 with electronic components 100 embedded in a carrier 128 according to an exemplary embodiment.

Any of said electronic components 100 may be constructed as described above referring to FIG. 1 to FIG. 17. However, a difference between the embodiment of FIG. 18 and the embodiments of FIG. 1 to FIG. 17 is that, according to FIG. 18, the electronic components 100 are embedded in rather than being surface mounted on the carrier 128. A further difference is that, according to FIG. 18, the carrier 128 is a laminate-type carrier.

The laminate-type carrier 128 comprises a laminated layer stack composed of a plurality of laminated layers 170, 172. Laminate-type carrier 128 is embodied as printed circuit board (PCB). In the illustrated example, the laminate-type carrier 128 comprises electrically insulating layers 170 which may be embodied as exterior prepreg layers and as a core 174 of FR4. Furthermore, the laminate-type carrier 128 comprises electrically conductive layers 172 embodied as copper layers on and in core 174 as well as on and in the prepreg layers. The electrically conductive layers 172 comprise horizontal traces and vertical through connections being interconnected with each other. A layer build-up in form of the electrically conductive layers 172 and the prepreg layers may be formed on both opposing main surfaces of core 174. On one or both opposing main surfaces of the laminated layer stack, a patterned solder resist 176 may be formed.

The electronic components 100 are partly surrounded by dielectric structure 120, which may for instance comprise resin. Metallization structures 106 of the electronic components 100 may be electrically coupled with electrically conductive layers 172.

The chip technology as described herein may be used for chip embedding in laminate. Thus, at least one electronic component 100 according to an exemplary embodiment may be embedded in dielectric insulating layer(s), e.g. laminate, prepreg, polymer, etc. Electronic components 100 may be connected to each other per redistribution layers and vias. Now referring specifically to FIG. 18, two power electronic components 100, i.e. high-side (HS) field-effect transistor chip 100′ and low-side (LS) field-effect transistor chip 100″ build a half bridge circuitry and are connected per redistribution layers with a driver electronic component 100′″.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. An electronic component, comprising:
a semiconductor body;
an active region in the semiconductor body;
at least one metallization structure arranged on or above the active region and comprising a stack having a barrier structure, an intermediate structure on the barrier structure and comprising nickel, and a copper and/or aluminium structure on the intermediate structure and comprising copper and/or aluminium; and
a dielectric structure connected to a sidewall of the stack.

2. An electronic component, comprising:
a semiconductor body;
an active region in the semiconductor body; and
at least one metallization structure on an opposing side of the semiconductor body with respect to the active region and comprising a stack having a barrier structure, an intermediate structure on the barrier structure and comprising nickel, and a copper and/or aluminium structure on the intermediate structure and comprising copper and/or aluminium;
wherein a surface of the semiconductor body on which the at least one metallization structure is arranged has a roughness Ra of at least 1 μm.

3. The electronic component according to claim 1, wherein the at least one metallization structure comprises a front side metallization structure on or above the active region.

4. The electronic component according to claim 1, wherein the at least one metallization structure comprises a base structure covered by the barrier structure and comprising aluminium.

5. The electronic component according to claim 1, wherein the copper and/or aluminium structure is a finish structure.

6. The electronic component according to claim 1, wherein different sections of at least one of the at least one metallization structure are separated by the dielectric structure, wherein for example said different sections are additionally separated by a further dielectric structure, for example stacked on said dielectric structure.

7. The electronic component according to claim 1, wherein the dielectric structure, and optionally a further dielectric structure, separates at least one of said at least one metallization structure from a further metallization structure which is provided without said stack.

8. The electronic component according to claim 1, wherein the stack is a horizontal planar layer sequence.

9. The electronic component according to claim 1, wherein the stack is a partially horizontal planar and partially slanted layer sequence, wherein for example a slanted portion of said layer sequence is arranged on a slanted sidewall of the dielectric structure.

10. The electronic component according to claim 1, wherein the dielectric structure comprises polyimide and/or an epoxy material.

11. The electronic component according to claim 2, wherein the at least one metallization structure comprises a back side metallization structure opposing the active region.

12. The electronic component according to claim 2, wherein the copper and/or aluminium structure is a seed structure.

13. The electronic component according to claim 12, comprising a bulk metal structure, for instance made of copper, on the seed structure.

14. The electronic component according to claim 1, wherein the intermediate structure is made of nickel-vanadium or nickel-silicon.

15. The electronic component according to claim 1, comprising at least one of the following features:
wherein the barrier structure comprises titanium, wherein for example the barrier structure is made of titanium, titanium-tungsten, and/or titanium nitride;
wherein the intermediate structure is an adhesion promoting structure;
comprising a solder structure on the copper and/or aluminium structure;
wherein the barrier structure is a barrier layer, the intermediate structure is an intermediate layer, and/or the copper and/or aluminium structure is a copper and/or aluminium layer;
wherein a thickness of the barrier structure is in a range from 50 nm to 500 nm, in particular in a range from 100 nm to 300 nm;
wherein a thickness of the intermediate structure is not more than 150 nm, in particular in a range from 10 nm to 100 nm;
wherein a thickness of the copper and/or aluminium structure is in a range from 10 nm to 1000 nm, in particular in a range from 50 nm to 500 nm;
comprising a passivation layer, for example comprising silicon oxide and/or silicon nitride, separating at least part of at least one of the at least one metallization structure with respect to the dielectric structure;
wherein the barrier structure has a larger lateral extension than a smaller lateral extension of the intermediate structure and the copper and/or aluminium structure.

16. A package, comprising:
a carrier; and
an electronic component according to claim 1 and being mounted on and/or in the carrier;
wherein at least one of the at least one metallization structure of the electronic component is electrically coupled with the carrier.

17. The package according to claim 16, comprising at least one of the following features:
wherein the electronic component is surface mounted on or is embedded in the carrier;
wherein the carrier comprises one of the group consisting of a leadframe structure, a ceramic sheet with metallic layers on both opposing main surfaces thereof, and a laminate;
comprising a solder structure between the carrier and at least one of the at least one metallization structure of the electronic component;
comprising a clip connected with at least one of the at least one metallization structure by a solder structure;
comprising a bond wire connected with at least one of the at least one metallization structure.

18. A method of manufacturing an electronic component, wherein the method comprises:
forming an active region in a semiconductor body;
forming at least one metallization structure on or above the active region and with a stack having a barrier structure, an intermediate structure on the barrier structure and comprising nickel, and a copper and/or aluminium structure on the intermediate structure and comprising copper and/or aluminium; and
connecting a dielectric structure to a sidewall of the stack.

19. A method of manufacturing an electronic component, wherein the method comprises:
forming an active region in a semiconductor body;
forming at least one metallization structure on an opposing side of the semiconductor body with respect to the active region and with a stack having a barrier structure, an intermediate structure on the barrier structure and comprising nickel, and a copper and/or aluminium structure on the intermediate structure and comprising copper and/or aluminium; and
arranging the at least one metallization structure on a surface of the semiconductor body which has a roughness Ra of at least 1 μm.

20. The method according to claim 18, comprising at least one of the following features:
wherein the method comprises forming at least one of the barrier structure, the intermediate structure, and/or the copper and/or aluminium structure by physical vapor deposition;
wherein the method comprises patterning at least two of the barrier structure, the intermediate structure, and the copper and/or aluminium structure in common;
wherein the method comprises patterning the barrier structure, the intermediate structure, and/or the copper and/or aluminium structure by wet chemically etching.
